(19) United States
(12) Patent Application Publication
(10) Pub. No.: US 2025/0358933 A1
(43) Pub. Date: Nov. 20, 2025

(54) PRINTED CIRCUIT BOARD LAMINATED DEVICE

(71) Applicant: Tien-Ming CHOU, Taichung City (TW)

(72) Inventor: Tien-Ming CHOU, Taichung City (TW)

(21) Appl. No.: 19/205,317

(22) Filed: May 12, 2025

(30) Foreign Application Priority Data
May 14, 2024 (TW) 113117759

(51) Int. Cl. H05K 1/18; H05K 1/14

(52) U.S. Cl. CPC H05K 1/181; H05K 1/141; H05K 1/144; H05K 2201/041; H05K 2201/044; H05K 2201/10098; H05K 2201/10121; H05K 2201/10522; H05K 2201/2036

(57) ABSTRACT

A printed circuit board laminated device includes a circuit board unit, a bracket unit, a cover plate unit and a coupled unit. The circuit board unit includes a first control circuit and a second control circuit disposed on a circuit board body. The bracket unit includes a hollow bracket body disposed on the circuit board unit along a laminating direction. The cover plate unit is disposed on the bracket unit along the laminating direction and opposite to the circuit board unit to cooperatively define a compartment. The coupled unit includes first and second coupled elements which are securely connected with the circuit board body and in the compartment and which are respectively and electrically connected with the first and second control circuits. The second coupled element responds to the first coupled element to generate a sensing signal.

### CROSS-REFERENCE TO RELATED APPLICATION

This application claims priority to Taiwanese Patent Application No. 113117759, filed on May 14, 2024, and incorporated by reference herein in its entirety.

### FIELD

The disclosure relates to an electronic device, and more particularly to a printed circuit board laminated device.

### BACKGROUND

A conventional optical coupler used for electrical isolation includes a lower housing half, an upper housing half connected with and attached to the lower housing half to define a compartment and a light passageway therebetween, a light emitting element disposed on the lower housing half and in the compartment, and an optical sensing element (such as an optical transistor) disposed on the upper housing half and in the compartment. The light emitted from the light emitting element is detected by the optical sensing element through the light passageway.

However, since the light emitting element and the optical sensing element are respectively disposed on the lower housing half and the upper housing half, alignment of the light emitting element with the optical sensing element is not easy to achieve due to manufacturing tolerance of the housing halves, which adversely affects the optical coupling effect of the optical coupler.

### SUMMARY

Therefore, an object of the disclosure is to provide a printed circuit board laminated device that can alleviate at least one of the drawbacks of the prior art.

According to the disclosure, the printed circuit board laminated device includes a circuit board unit, a bracket unit, a cover plate unit and a coupled unit. The circuit board unit includes a circuit board body, a first control circuit and a second control circuit which are disposed on the circuit board body. The bracket unit includes a hollow bracket body which is disposed on the circuit board unit along a laminating direction. The cover plate unit is disposed on the bracket unit along the laminating direction and is opposite to the circuit board unit. The cover plate unit, the bracket body and the circuit board body cooperatively define a compartment thereamong. The coupled unit includes a first coupled element which is electrically connected with the first control circuit and securely connected with the circuit board body, and a second coupled element which is electrically connected with the second control circuit and securely connected with the circuit board body. Both of the first coupled element and the second coupled element are disposed in the compartment such that the second coupled element responds to the first coupled element to generate a sensing signal.

With the first coupled element and the second coupled element cooperatively and retainingly connected with the circuit board body, the relative positions of the first coupled element and the second coupled element may be predetermined and arranged easily so as to reduce misalignment and deflection between the first coupled element and the second coupled element to improve the reliability of the printed circuit board laminated device.

### BRIEF DESCRIPTION OF THE DRAWINGS

Other features and advantages of the disclosure will become apparent in the following detailed description of the embodiments with reference to the accompanying drawings. It is noted that various features may not be drawn to scale.

FIG. 1 is a perspective view illustrating a first embodiment of a printed circuit board laminated device according to the disclosure.

FIG. 2 is an exploded perspective view of the first embodiment.

FIG. 3 is a perspective view illustrating a second embodiment of the printed circuit board laminated device according to the disclosure.

FIG. 4 is an exploded perspective view of the second embodiment.

FIG. 5 is an exploded perspective view of the second embodiment taken from another angle.

FIG. 6 is a perspective view illustrating a third embodiment of the printed circuit board laminated device according to the disclosure.

FIG. 7 is an exploded perspective view of the third embodiment.

FIG. 8 is a perspective view illustrating a fourth embodiment of the printed circuit board laminated device according to the disclosure.

FIG. 9 is an exploded perspective view of the fourth embodiment.

FIG. 10 is an exploded perspective view of the fourth embodiment taken from another angle.

FIG. 11 is a perspective view illustrating the fourth embodiment mounted on a circuit board extending in a laminating direction and a front-rear direction.

FIG. 12 is a perspective view illustrating the fourth embodiment mounted on the circuit board extending in the front-rear direction and a left-right direction and having an upwardly facing connecting surface.

FIG. 13 is a perspective view illustrating the fourth embodiment mounted on the circuit board extending in the front-rear direction and the left-right direction and having a downwardly facing connecting surface.

FIG. 14 is a perspective view illustrating a fifth embodiment of the printed circuit board laminated device according to the disclosure.

FIG. 15 is an exploded perspective view of the fifth embodiment.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

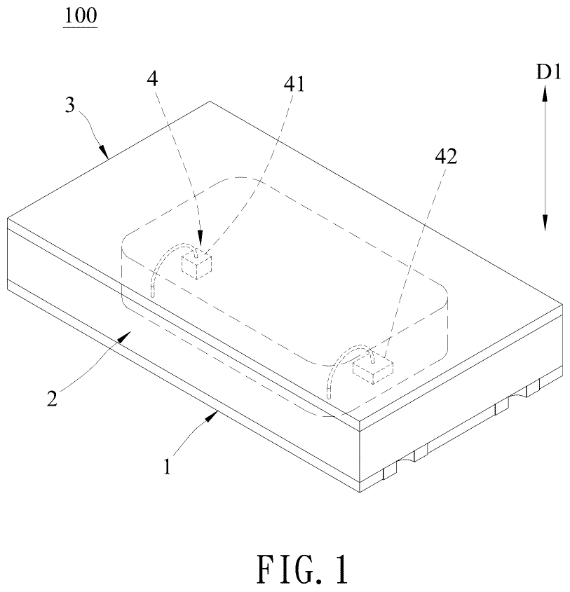

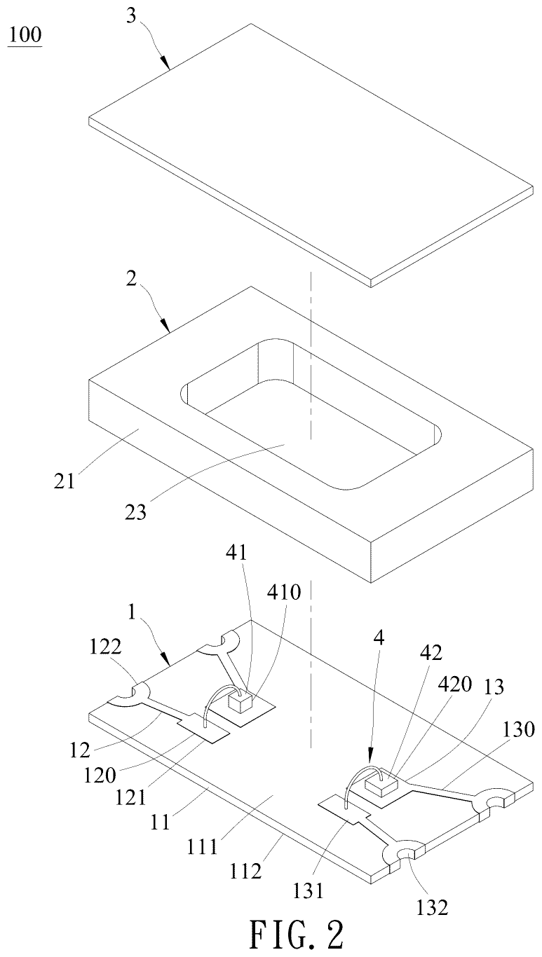

Referring to FIGS. 1 and 2, a first embodiment of a printed circuit board laminated device 100 according to the disclosure is an optocoupler, and includes a circuit board unit 1, a bracket unit 2, a cover plate unit 3 and a coupled unit 4.

The circuit board unit 1 includes a circuit board body 11, a first control circuit 12 and a second control circuit 13 which are disposed on the circuit board body 11. In this embodiment, the circuit board body 11 is a printed circuit board, the first control circuit 12 has a light emitting circuit 120, and the second control circuit 13 has an optical sensing circuit 130. The circuit board body 11 has a first mounting surface 111 which is connected with and attached to the bracket unit 2, a second mounting surface 112 opposite to the first mounting surface 111, and a first peripheral surface 113 interconnecting the first mounting surface 111 and the second mounting surface 112.

The light emitting circuit 120 has a light emitting driving end 121 which is disposed on the first mounting surface 111, and a light emitting power suppling end 122 which is electrically connected with the light emitting driving end 121. In this embodiment, the light emitting circuit 120 is laid out on the circuit board body 120.

The optical sensing circuit 130 has an optical sensing receiving end 131 which is disposed on the first mounting surface 111, and an optical sensing transmitting end 132 which is electrically connected with the optical sensing receiving end 131. In this embodiment, the optical sensing circuit 130 is laid out on the circuit board body 11. In the drawings, the power end and associated wires of the optical sensing circuit 130 are omitted for the sake of clarity.

The bracket unit 2 includes a hollow bracket body 21 which is disposed on the circuit board unit 1 along a laminating direction (D1).

The cover plate unit 3 is disposed on the bracket unit 2 along the laminating direction (D1) and is opposite to the circuit board unit 1. The cover plate unit 3, the bracket body 21 and the circuit board body 11 cooperatively define a compartment 23 thereamong for receiving the coupled unit 4.

The coupled unit 4 includes a first coupled element 41 which is electrically connected with the first control circuit 12 and securely connected with the circuit board body 11, and a second coupled element 42 which is electrically connected with the second control circuit 13 and securely connected with the circuit board body 11. Both of the first coupled element 41 and the second coupled element 42 are disposed in the compartment 23 such that the second coupled element 42 optically responds to the first coupled element 41 to generate a sensing signal. In this embodiment, the first coupled element 41 has a light emitting element 410, and the second coupled element 42 has an optical sensing element 420 such that the light emitting element 410 is disposed in the compartment 23 for emitting light beams, and the optical sensing element 420 is disposed in the compartment 23 to detect the light beams emitted from the light emitting element 410 so as to generate the sensing signal. For example, the optical sensing element 420 may be, not limited to, an optical transistor, a photodiode, a photoresistor, etc.

The light emitting driving end 121 is electrically connected with the light emitting element 410. The optical sensing receiving end 131 is electrically connected with the optical sensing element 420. During operation, the light emitting power supplying end 122 receives an external control signal to drive the light emitting element 410 through the light emitting driving end 121 to emit the light beams. Subsequently, the optical sensing receiving end 131 receives the sensing signal from the optical sensing element 420 to indicate that the optical sensing element 420 has detected the light beams emitted from the light emitting element 410.

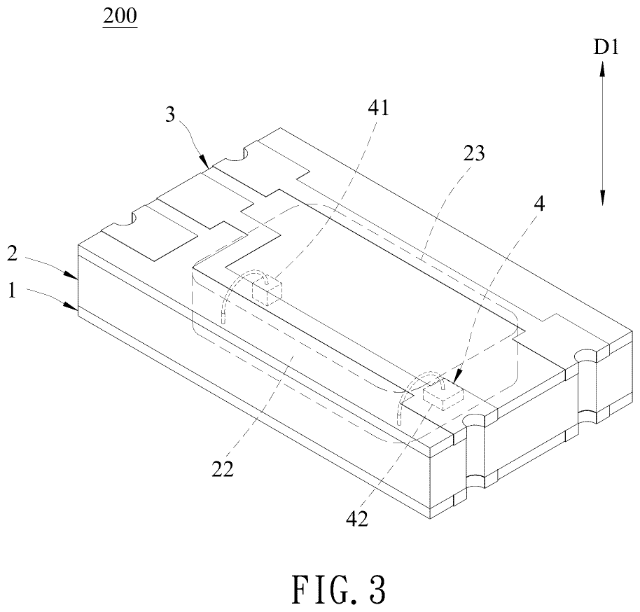

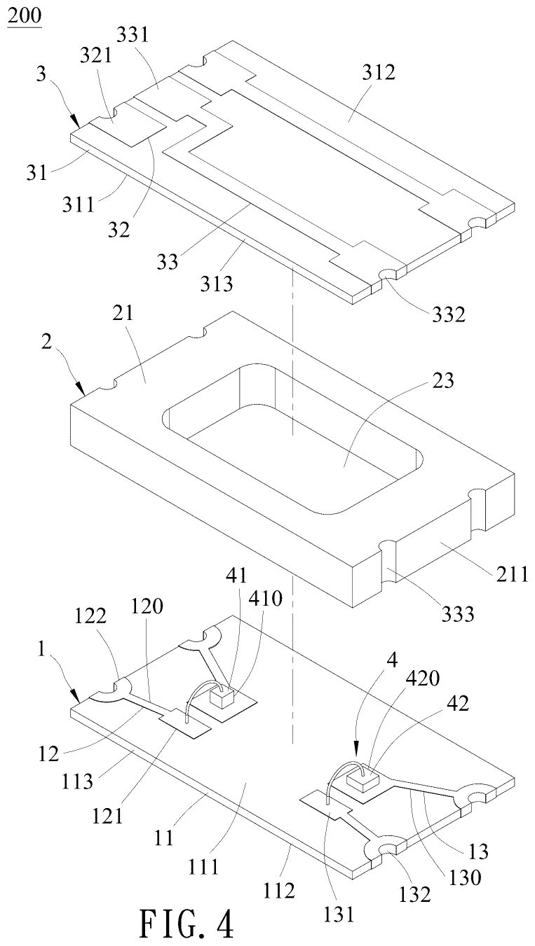

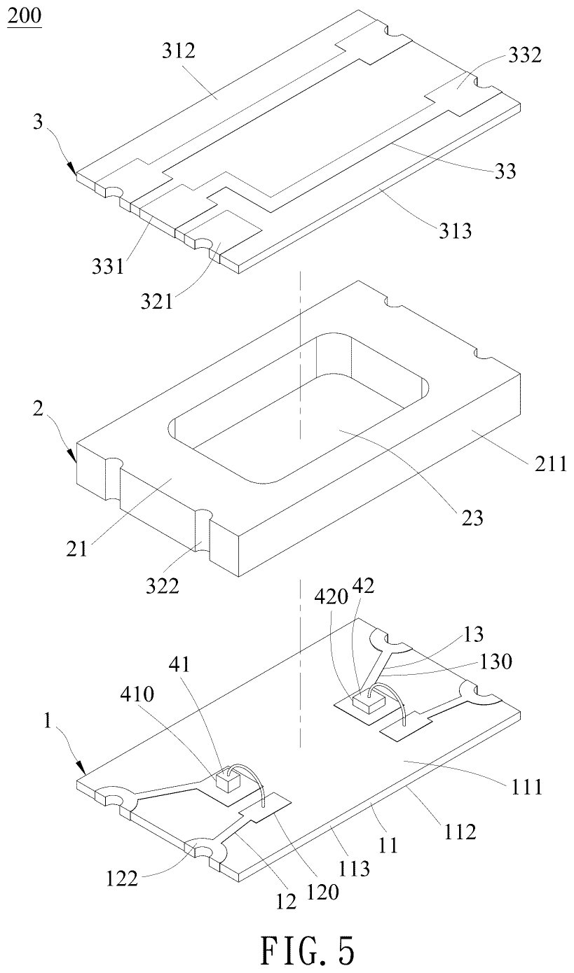

With reference to FIGS. 3 to 5, in a second embodiment of the printed circuit board laminated device 200 which is an optocoupler, the bracket body 21 has a middle peripheral surface 211 opposite to the compartment 23. The cover plate unit 3 includes a cover plate body 31, a conducting light emitting circuit 32 and a conducting optical sensing circuit 33 which are disposed on the cover plate body 31. In this embodiment, the cover plate unit 3 is a printed circuit board.

The cover plate body 31 has a third mounting surface 311 which is connected with and attached to the bracket unit 2, a fourth mounting surface 312 opposite to the third mounting surface 311, and a second peripheral surface 313 interconnecting the third mounting surface 311 and the fourth mounting surface 312.

The conducting light emitting circuit 32 is laid out on the cover plate body 31, extends from the third mounting surface 311 to the fourth mounting surface 312, and is electrically connected with the light emitting circuit 120. Specifically, the conducting light emitting circuit 32 has a conducting power supplying end 321 which is electrically connected with the light emitting power supplying end 122 and disposed on one of the fourth mounting surface 312 and the second peripheral surface 313, and an auxiliary power supplying end 322 which is disposed between the light emitting power supplying end 122 and the conducting power supplying end 321. The conducting power supplying end 321, similar to the light emitting power supplying end 122, receives a control signal to drive the light emitting element 410 through the light emitting driving end 121 to emit light beams.

The conducting power supplying end 321 and the auxiliary power supplying end 322 are of a patch-type conductor, and are made from silver, copper, gold, etc. The conducting power supplying end 321 is attached to one of the fourth mounting surface 312 and the second peripheral surface 313 and at a side adjacent to the light emitting power supplying end 122. The auxiliary power supplying end 322 is attached to the middle peripheral surface 211 and at a side adjacent to the light emitting power supplying end 122 so as to contact and communicate with the light emitting power supplying end 122 and the conducting power supplying end 321.

The conducting optical sensing circuit 33 is laid out on the cover plate body 31, extends from the third mounting surface 311 to the fourth mounting surface 312, and is electrically connected with the optical sensing circuit 130. Specifically, the conducting optical sensing circuit 33 has a conducting transmitting end 331 which is electrically connected with the optical sensing transmitting end 132 and disposed on one of the fourth mounting surface 312 and the second peripheral surface 313, an extending transmitting end 332 which is electrically connected with the conducting transmitting end 331, and an auxiliary transmitting end 333 which is disposed on the middle peripheral surface 211 and electrically connected between the extending transmitting end 332 and the optical sensing transmitting end 132.

The conducting transmitting end 331, the extending transmitting end 332 and the auxiliary transmitting end 333 are of a patch-type conductor, and are made from silver, copper, gold, etc. The conducting transmitting end 331 is attached to one of the fourth mounting surface 312 and the second peripheral surface 313 and at a side remote from the optical sensing transmitting end 132. The extending transmitting end 332 is attached to one of the fourth mounting surface 312 and the second peripheral surface 313 and at a side adjacent to the optical sensing transmitting end 132. The auxiliary transmitting end 333 is attached to the middle peripheral surface 211 and at a side adjacent to the optical sensing transmitting end 132 so as to contact and communicate with the optical sensing transmitting end 132 and the conducting transmitting end 331. In other words, the conducting optical sensing circuit 33 is disposed on the fourth mounting surface 312 and extends from a side adjacent to the optical sensing transmitting end 132 to an opposite side remote from the optical sensing transmitting end 132.

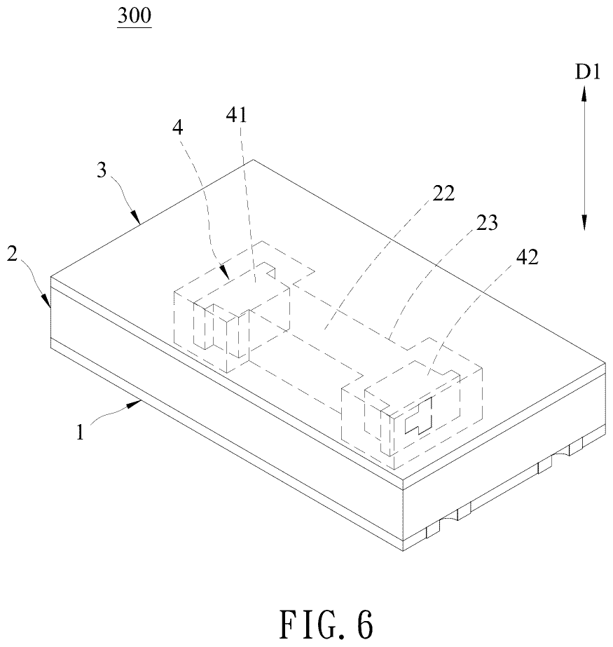

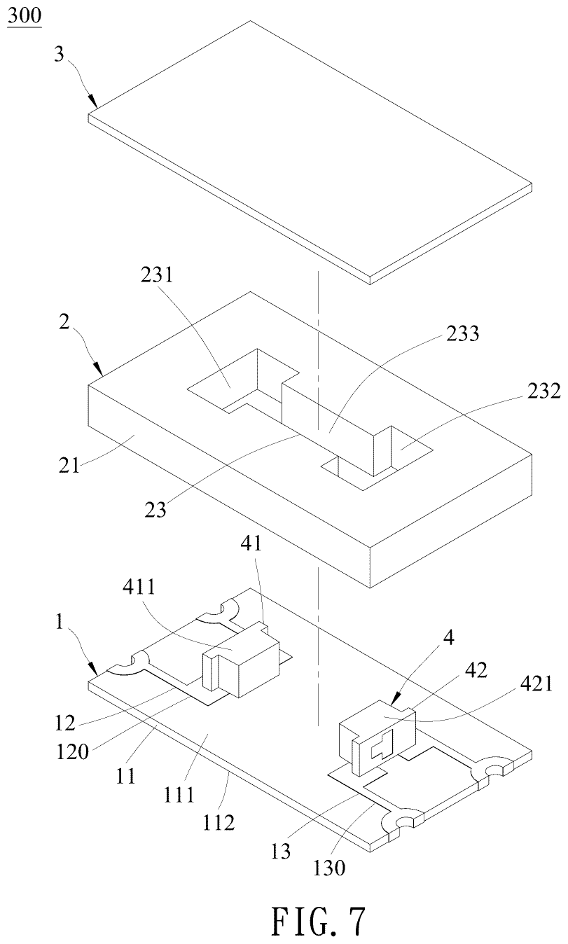

With reference to FIGS. 6 and 7, in a third embodiment of the printed circuit board laminated device 300 which is an optocoupler, at least part of the light emitting circuit 120 is packaged with the light emitting element 410 to form a light emitter 411. At least part of the optical sensing circuit 130 is packaged with the optical sensing element 420 to form a light receiver 421. The bracket unit 2 further includes a translucent medium portion 22. The translucent medium portion 22 cooperates with the coupled unit 4 to be filled in the compartment 23. The compartment 23 has an emitting chamber 231 for retainingly receiving the light emitter 411, a receiving chamber 232 for retainingly receiving the light receiver 421, and a light passageway 233 communicated with both of the emitting chamber 231 and the receiving chamber 232.

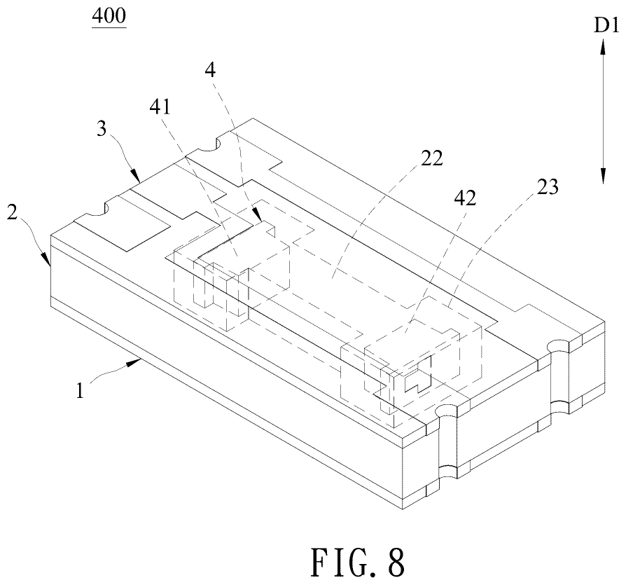

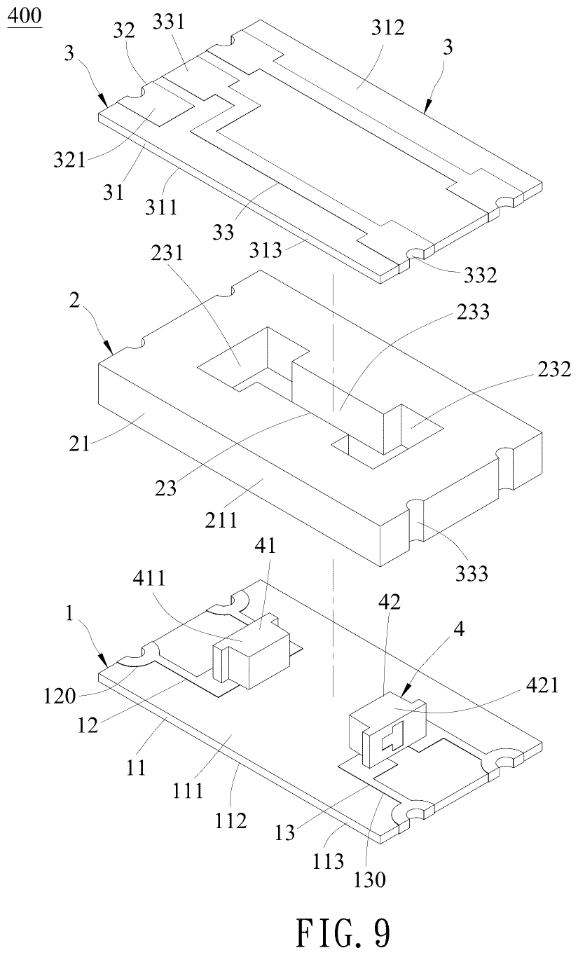

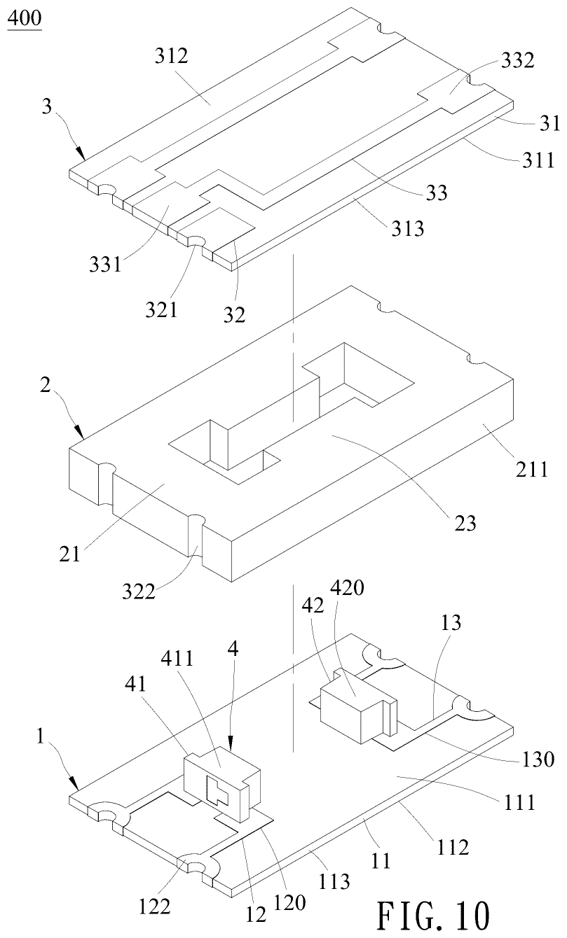

With reference to FIGS. 8 to 10, in a fourth embodiment of the printed circuit board laminated device 400 which is an optocoupler similar to the third embodiment, at least part of the light emitting circuit 120 is packaged with the light emitting element 410 to form a light emitter 411. At least part of the optical sensing circuit 130 is packaged with the optical sensing element 420 to form a light receiver 421. The compartment 23 has an emitting chamber 231 for retainingly receiving the light emitter 411, a receiving chamber 232 for retainingly receiving the light receiver 421, and a light passageway 233 communicated with both of the emitting chamber 231 and the receiving chamber 232.

The cover plate unit 3 includes a cover plate body 31, a conducting light emitting circuit 32 and a conducting optical sensing circuit 33.

The cover plate body 31 has a third mounting surface 311 which is connected with and attached to the bracket unit 2, a fourth mounting surface 312 opposite to the third mounting surface 311, and a second peripheral surface 313 interconnecting the third mounting surface 311 and the fourth mounting surface 312.

The conducting light emitting circuit 32 has a conducting power supplying end 321 which is electrically connected with the light emitting power supplying end 122, and an auxiliary power supplying end 322 which is disposed between the light emitting power supplying end 122 and the conducting power supplying end 321. The conducting power supplying end 321 is attached to the fourth mounting surface 312 and at a side adjacent to the light emitting power supplying end 122. The auxiliary power supplying end 322 is attached to the middle peripheral surface 211 and at a side adjacent to the light emitting power supplying end 122 so as to contact and communicate with the light emitting power supplying end 122 and the conducting power supplying end 321.

The conducting optical sensing circuit 33 has a conducting transmitting end 331 which is disposed on one of the fourth mounting surface 312 and the second peripheral surface 313, an extending transmitting end 332 which is electrically connected with the conducting transmitting end 331, and an auxiliary transmitting end 333 which is disposed on the middle peripheral surface 211 and electrically connected between the extending transmitting end 332 and the optical sensing transmitting end 132.

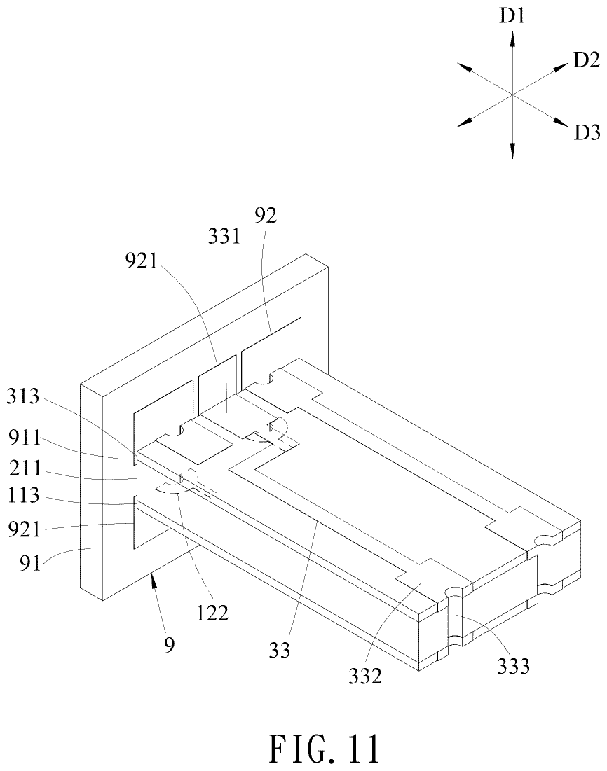

With reference to FIGS. 11 to 13, during operation, the printed circuit board laminated device 400 of one of the second embodiment and the fourth embodiment may be mounted on an external circuit board unit 9. The external circuit board unit 9 may be mountable along a variety of directions. Specifically, the external circuit board unit 9 includes an external circuit board body 91 having a coupled surface 911, and an external circuit 92 disposed on the coupled surface 911. The external circuit 92 has a plurality of connecting terminal portions 921.

Referring to FIG. 11, the external circuit board unit 9 extends along both of the laminating direction (D1) and a front-rear direction (D2) which is transverse to the laminating direction (D1), and the laminating direction (D1) is in an upright direction. The first peripheral surface 113 of the circuit board body 11, the second peripheral surface 313 of the cover plate body 31 and the middle peripheral surface 211 of the bracket body 21 are disposed on the coupled surface 911, and the light emitting power supplying end 122 and the conducting transmitting end 331 are electrically connected with the corresponding connecting terminal portions 921, respectively, so as to control and operate the light emitting element 410 and the optical sensing element 420 through the external circuit board unit 9.

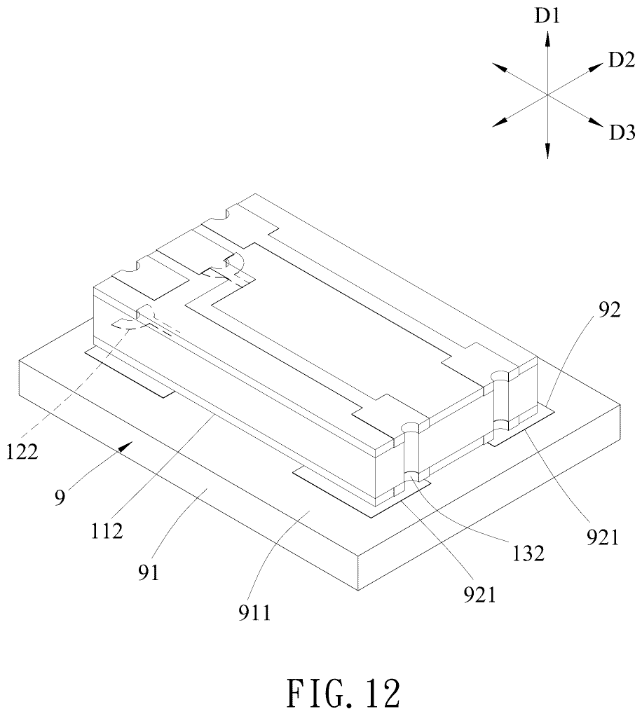

Referring to FIG. 12, the external circuit board unit 9 extends along the front-rear direction (D2) and a left-right direction (D3) which is transverse to the front-rear direction (D2), and the coupled surface 911 faces upwardly. The second mounting surface 112 of the circuit board body 11 is disposed on the coupled surface 911, and the light emitting power supplying end 122 and the optical sensing transmitting end 132 are electrically connected with the corresponding connecting terminal portions 921, respectively, so as to control and operate the light emitting element 410 and the optical sensing element 420 through the external circuit board unit 9.

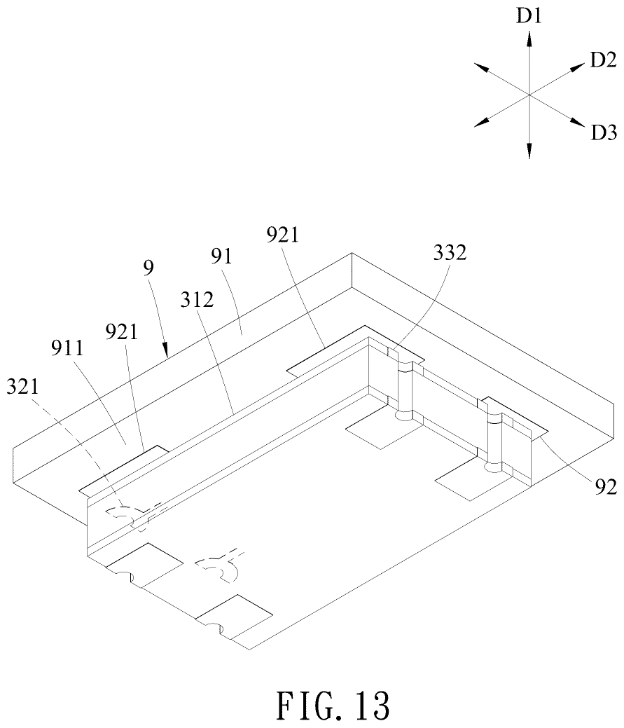

Referring to FIG. 13, the external circuit board unit 9 extends along the front-rear direction (D2) and the left-right direction (D3), and the coupled surface 911 faces downwardly. The fourth mounting surface 312 of the cover plate body 31 is disposed on the coupled surface 911, and the conducting power supplying end 321 and the extending transmitting end 332 are electrically connected with the corresponding connecting terminal portions 921, respectively, so as to control and operate the light emitting element 410 and the optical sensing element 420 through the external circuit board unit 9.

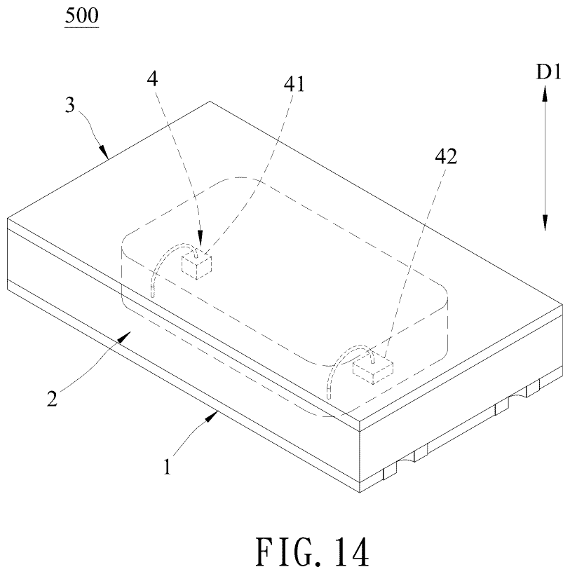

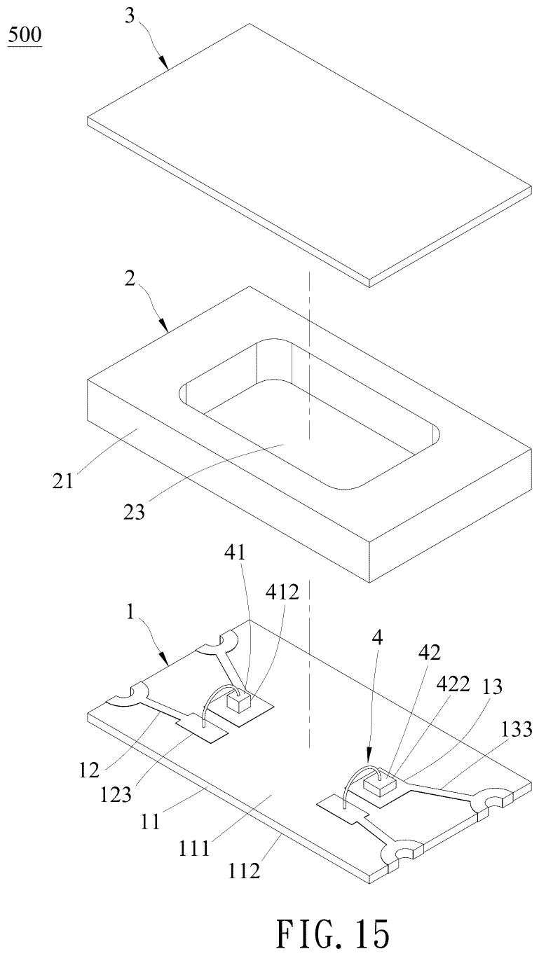

With reference to FIGS. 14 and 15, a fifth embodiment of the printed circuit board laminated device 500 is an antenna transmitting coupling calibration device for simulating coupling channels with antenna transmission.

Specifically, the first control circuit 12 has a first antenna circuit 123, and the second control circuit 13 has a second antenna circuit 133. The first coupled element 41 has a transmitting antenna 412, and the second coupled element 42 has a receiving antenna 422. The transmitting antenna 412 is disposed in the compartment 23 for emitting a radio frequency (RF) signal (such as radio wave or microwaves), and the receiving antenna 422 is disposed in the compartment 23 for receiving the RF signal emitted from the transmitting antenna 412 to generate the sensing signal.

As illustrated, in the printed circuit board laminated device 100, 200, 300, 400 of one of the first, second, third and fourth embodiments, with the light emitting element 410 and the optical sensing element 420 cooperatively and retainingly connected with the circuit board body 11, the relative positions of the light emitting element 410 and the optical sensing element 420 may be predetermined and arranged easily. Additionally, with the bracket body 21 and the translucent medium portion 22 for cooperatively retaining the light emitting element 410 and the optical sensing element 420 on the circuit board body 11, misalignment and deflection between the light emitting element 410 and the optical sensing element 420 may be reduced so as to improve the reliability of the printed circuit board laminated device.

Moreover, in the printed circuit board laminated device 200, 400 of one of the second and fourth embodiments, with the conducting light emitting circuit 32 laid out on the cover plate body 31, extending from the third mounting surface 311 to the fourth mounting surface 312 and electrically connected with the light emitting circuit 120, and the conducting optical sensing circuit 33 laid out on the cover plate body 31, extending from the third mounting surface 311 to the fourth mounting surface 312 and electrically connected with the optical sensing circuit 130, the printed circuit board laminated device may be mounted on the external circuit board unit 9 along a variety of directions so as to increase the compatibility of the printed circuit board laminated device 200, 400 with external circuit board units along a variety of directions.

Furthermore, in the printed circuit board laminated device 500 of the fifth embodiment, with the transmitting antenna 412 and the receiving antenna 422 cooperatively and retainingly connected with the circuit board body 11, the relative positions of the transmitting antenna 412 and the receiving antenna 422 may be predetermined and arranged easily so as to reduce the error of transmission between the transmitting antenna 412 and the receiving antenna 422 such that a testing environment provided by the printed circuit board laminated device 500 may be the same. Therefore, the printed circuit board laminated device of the disclosure is easy to operate and has great reliability and compatibility.

In the description above, for the purposes of explanation, numerous specific details have been set forth in order to provide a thorough understanding of the embodiments. It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what are considered the exemplary embodiments, it is understood that this disclosure is not limited to the disclosed embodiments but is intended to cover various arrangements included within the spirit and scope of the broadest interpretation so as to encompass all such modifications and equivalent arrangements.

What is claimed is:

1. A printed circuit board laminated device, comprising:
a circuit board unit including a circuit board body, a first control circuit and a second control circuit which are disposed on said circuit board body;
a bracket unit including a hollow bracket body which is disposed on said circuit board unit along a laminating direction;
a cover plate unit disposed on said bracket unit along the laminating direction and opposite to said circuit board unit, wherein said cover plate unit, said bracket body and said circuit board body cooperatively define a compartment thereamong; and
a coupled unit including a first coupled element which is electrically connected with said first control circuit and securely connected with said circuit board body, and a second coupled element which is electrically connected with said second control circuit and securely connected with said circuit board body, both of said first coupled element and said second coupled element being disposed in said compartment such that said second coupled element responds to said first coupled element to generate a sensing signal.

2. The printed circuit board laminated device of claim 1, wherein said first control circuit has a light emitting circuit, said second control circuit has an optical sensing circuit, said first coupled element has a light emitting element, and said second coupled element has an optical sensing element such that said light emitting element is disposed in said compartment for emitting light beams, said optical sensing element is disposed in said compartment to detect the light beams emitted from said light emitting element so as to generate the sensing signal.

3. The printed circuit board laminated device of claim 2, wherein said bracket unit further includes a translucent medium portion, said translucent medium portion cooperating with said coupled unit to be filled in said compartment.

4. The printed circuit board laminated device of claim 2, wherein said cover plate unit includes a cover plate body, a conducting light emitting circuit and a conducting optical sensing circuit which are disposed on said cover plate body.

5. The printed circuit board laminated device of claim 4, wherein said circuit board body has a first mounting surface which is connected with and attached to said bracket unit, and a second mounting surface which is opposite to said first mounting surface, said cover plate body having a third mounting surface which is connected with and attached to said bracket unit, and a fourth mounting surface which is opposite to said third mounting surface, said conducting light emitting circuit extending from said third mounting surface to said fourth mounting surface and being electrically connected with said light emitting circuit, said conducting optical sensing circuit extending from said third mounting surface to said fourth mounting surface and being electrically connected with said optical sensing circuit.

6. The printed circuit board laminated device of claim 5, adapted to be mounted on an external circuit board unit, wherein said circuit board body further has a first peripheral surface interconnecting said first mounting surface and said second mounting surface, said bracket body having a middle peripheral surface opposite to said compartment, said light emitting circuit having a light emitting driving end which is disposed on said first mounting surface and electrically connected with said light emitting element, and a light emitting power suppling end which is electrically connected with said light emitting driving end, said optical sensing circuit having an optical sensing receiving end which is disposed on said first mounting surface and electrically connected with said optical sensing element, and an optical sensing transmitting end which is electrically connected with said optical sensing receiving end.

7. The printed circuit board laminated device of claim 6, wherein said cover plate body further has a second peripheral surface interconnecting said third mounting surface and said fourth mounting surface, said conducting light emitting circuit having a conducting power supplying end which is electrically connected with said light emitting power supplying end and disposed on one of said fourth mounting surface and said second peripheral surface, and an auxiliary power supplying end which is disposed between said light emitting power supplying end and said conducting power supplying end, said conducting optical sensing circuit having a conducting transmitting end which is electrically connected with said optical sensing transmitting end and disposed on one of said fourth mounting surface and said second peripheral surface, an extending transmitting end which is electrically connected with said conducting transmitting end, and an auxiliary transmitting end which is disposed on said middle peripheral surface and electrically connected between said extending transmitting end and said optical sensing transmitting end, wherein one of said light emitting circuit and said conducting light emitting circuit and one of said optical sensing circuit and said conducting optical sensing circuit are electrically connected with the external circuit board unit.

8. The printed circuit board laminated device of claim 2, wherein at least part of said light emitting circuit is packaged with said light emitting element to form a light emitter, and at least part of said optical sensing circuit is packaged with said optical sensing element to form a light receiver.

9. The printed circuit board laminated device of claim 8, wherein said compartment has an emitting chamber for retainingly receiving said light emitter, a receiving chamber for retainingly receiving said light receiver, and a light passageway communicated with both of said emitting chamber and said receiving chamber.

10. The printed circuit board laminated device of claim 1, wherein said first control circuit has a first antenna circuit, said second control circuit has a second antenna circuit, said first coupled element has a transmitting antenna, and said second coupled element has a receiving antenna such that said transmitting antenna is disposed in said compartment for emitting a radio frequency (RF) signal, and said receiving antenna is disposed in said compartment for receiving the RF signal emitted from said transmitting antenna to generate the sensing signal.
